(19) United States
(12) Patent Application Publication
(10) Pub. No.: US 2002/0070453 A1
(43) Pub. Date: Jun. 13, 2002

(54) SEMICONDUCTOR DEVICE AND METHOD OF PRODUCING THEREOF

(76) Inventor: KOJI YAMAMOTO, Kyoto (JP)

Correspondence Address: MORGAN LEWIS & BOCKIUS LLP, 1111 PENNSYLVANIA AVENUE NW, WASHINGTON, DC, 20004, US

(21) Appl. No.: 09/441,205

(22) Filed: Nov. 16, 1999

(30) Foreign Application Priority Data
Nov. 17, 1998 (JP) 10-326650

(51) Int. Cl. H01L 23/48

(52) U.S. Cl. 257/758

(57) ABSTRACT

In a multi-layer wiring structure, since a metallic plug 34 is wired over an intermediate wiring layer 24, no connecting layer is required for connecting upper and lower metallic plugs. Therefore, the interval L1 between the intermediate wiring layer 24 and the center of the metallic plug 34 and the interval L2 between the respective centers of the adjacent metallic plugs 34 are not determined depending upon the width of the connecting layer. Accordingly, these intervals can be reduced as compared with the prior art. This makes it possible to reduce the chip size.

### BACKGROUND OF THE INVENTION

1. Field of the Invention

The present invention relates to a semiconductor and method of producing thereof, and more particularly to a multi-layer wiring structure and its manufacturing method which is applied to a highly-integrated such as an LSI, VLSI, etc. and has a lowermost wiring layer, uppermost wiring layer and at least one intermediate wiring layer, and its manufacturing method.

2. Description of the Related Art

In a conventional multi-layer wiring structure 1 which is applied to an LSI, VLSI, etc. as shown in FIG. 11, as the case may be, an wiring layer 2 and another wiring layer 3 thereabove are arranged over at least one wiring layer 4. In this case, in the prior art, between the wiring layer 2 and the wiring layer 4, the following structure is formed. A first metallic plug 6 is embedded in an interlayer insulating film 5. A connecting layer (connecting pad) 7 is formed on the first metallic plug 6. A second metallic plug 9 which is electrically connected to the connecting layer 7 is embedded in another interlayer insulating film 8 between the wiring layer 4 and wiring layer 3. Such a structure is well known as STACKED VIA structure.

In such a structure, the wiring layer 4 and the connecting layer 7, the connecting layer 7 and another connecting layer 7 must be spaced apart from each other by a prescribed interval A so that they are not brought into contact with each other. On the other hand, the width of the connecting layer 7 must be much larger than that of the second metallic plug 9 in order to assure the electrical connection with the second metallic plug 9. Therefore, the interval L1 between the wiring layer 4 and the center of the second metallic plug 9 and the interval L2 between the respective centers of the second metallic plugs 9 are determined depending upon the width C of the connecting layer 7 as well as the prescribed interval A. This makes it difficult to miniaturize the chip size.

### SUMMARY OF THE INVENTION

An object of the invention is to provide a multi-layer wiring structure which can be reduced in chip size.

In order to attain the above object of the present invention, in accordance with the present invention, there is provided a multi-layer wiring structure comprising: a lowermost wiring layer; an uppermost wiring layer; at least one intermediate wiring layer between the lowermost wiring layer and the uppermost wiring layer; and a current passage which connects the lowermost layer and the uppermost layer, the current passage having a conductive plug which is wired over the at least one intermediate wiring layer.

In accordance with the present invention, the metallic plug for electrically connecting the first wiring layer and the third wiring layer is wired over at least one intermediate wiring layer, i.e. second wiring layer, no connecting layer is required for connecting upper and lower conductive plugs. Therefore, the intervals between the conductive plug and wiring layer and between the adjacent conductive plugs are not determined depending upon the width of the connecting layer.

Preferably, in the semiconductor device, the conductive plug is made of a conductive film which is formed in a connecting hole by a high pressure embedding technique, the connecting hole being formed an insulating film covering the lowermost wiring layer and intermediate wiring layer.

In this structure, by using the high pressure embedding technique, the conductive plug can be embedded in the connecting hole having a high aspect ratio.

Preferably, in the semiconductor device, the connecting hole has an aspect ratio of 1.0-5.0.

If the aspect ratio of the connecting hole is smaller than 1.0, a void is formed so that the conductive film cannot be preferably embedded in the connecting hole. If the aspect ratio of the connecting hole is larger than 5.0, the connecting hole cannot be embedded completely. By decreasing the opening diameter so as to have a high aspect ratio, a reliable multi-layer wiring structure with a small occupied area can be manufactured.

Preferably, in the semiconductor device, the connecting hole has an opening diameter within a range between 0.2-1.0 μm. If the diameter of the connecting hole is not smaller than 1.0 μm, a void is sometimes formed. In these configurations, a reliable multi-layer wiring structure with a small occupied area can be manufactured.

In accordance with the present invention, there is provided a method of manufacturing a semiconductor device comprising the steps of:

forming a first wiring layer on a semiconductor substrate;

successively forming, on the first wiring layer, a first interlayer insulating film, a second wiring layer and a second interlayer insulating film;

forming a connecting hole in said first interlayer insulating film and said second interlayer insulating film so as to reach said first wiring layer over said second wiring layer; and

embedding a conductive plug in said connecting hole and forming a third wiring layer thereon.

In the method of manufacturing a semiconductor device, the conductive film is embedded by the high pressure embedding technique.

In the method of manufacturing a semiconductor device, preferably, the connecting hole has an aspect ratio of 1.0-5.0.

In the method of manufacturing a semiconductor device, preferably, the connecting hole has an opening diameter within a range between 0.2-1.0 μm.

In accordance with the present invention, there is provided a semiconductor device including a memory cell section composed of a MOSFET for switching and a capacitor connected thereto and a logic section including a CMOS circuit, comprising:

a semiconductor substrate in which MOSFETs for switching and CMOS circuit are formed;

a capacitor formed through a first interlayer insulating formed on a surface of the semiconductor substrate;

a second insulating film covering the capacitor and the entire semiconductor substrate;

conductive plugs formed to pass through the first and the second insulating film, wherein the capacitor and the MOSFETs are connected by connecting the conductive plugs to each other on an uppermost layer on the second insulating layer.

In such a configuration, in fabrication of a semiconductor device such as DRAM, FRAM, etc., which occupies a large area and requires a large number of times of photolithography, the number of man-hours can be reduced greatly and the cell size can be also greatly reduced.

Preferably, in the semiconductor device, the capacitor is a ferromagnetic capacitor.

In accordance with the present invention, since the intervals between the metallic plug and wiring layer and between the adjacent metallic plug, the chip size can be reduced.

The above and other objects and features of the present invention will be more apparent from the following description taken in conjunction with the accompanying drawings.

### BRIEF DESCRIPTION OF THE DRAWINGS

FIG. 1 is a schematic sectional view of an embodiment of a multi-layer wiring structure according to the present invention;

FIGS. 2A-2D are sectional views for explaining a method of manufacturing the multi-layer structure shown in FIG. 1;

FIGS. 3E-3G are sectional views for explaining a method of manufacturing the multi-layer structure shown in FIG. 1;

FIGS. 4H-4I are sectional views for explaining a method of manufacturing the multi-layer structure shown in FIG. 1;

FIG. 5J is a schematic sectional view of a modification of an multi-layer wiring structure according to the present invention; and

FIGS. 6A and 6B are sectional views for explaining a method of manufacturing the multi-layer structure shown in FIG. 5J;

FIGS. 7A and 7B are sectional views for explaining a method of manufacturing the multi-layer structure shown in FIGS. 5J;

FIGS. 8 is a sectional view for explaining a method of manufacturing the multi-layer structure shown in FIG. 5J;

FIG. 9 is a sectional view of the semiconductor device according to the second embodiment of the present invention; and

FIGS. 10 and 11 are schematic sectional views of a conventional multi-layer wiring structure.

### DESCRIPTION OF THE PREFERRED EMBODIMENTS

Embodiment 1

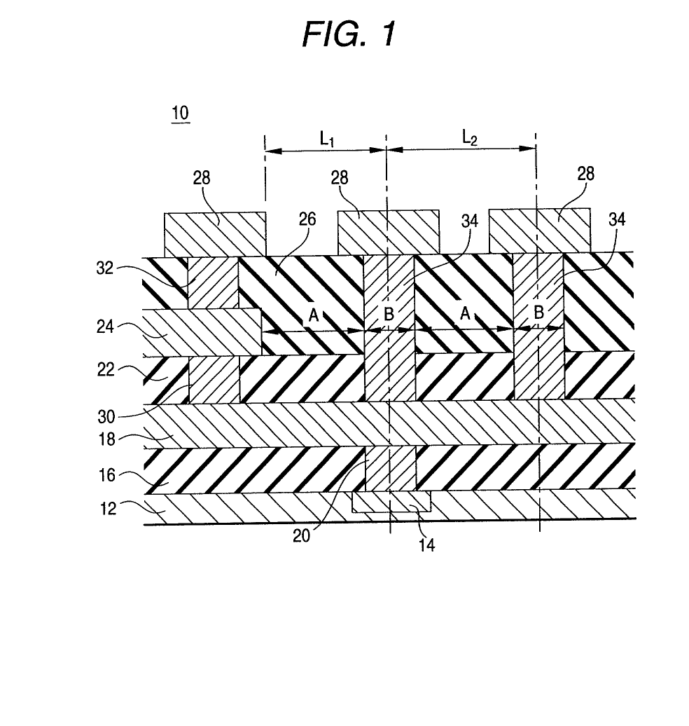

As shown in FIG. 1, a multi-layer wiring structure 10 according to this embodiment includes a semiconductor substrate (hereinafter simply referred to as “substrate”) 12 made of silicon (Si). In the upper area of the substrate 12, a conductive region 14 is formed. On the substrate 12, an interlayer insulating film 16 of e.g. silicon oxide (SiO₂) is formed. On the interlayer insulating film 16, a lowermost wiring layer 18 of aluminum (Al) is formed. The conductive area 14 and the lowermost wiring layer 18 are electrically connected to each other through a metallic plug 20 of aluminum (Al) which is embedded in the interlayer insulating film 16.

On the lowermost wiring layer 18, an interlayer insulating film 22 of silicon oxide (SiO₂) is formed, and on the interlayer insulating film 22, an intermediate wiring layer 24 of aluminum (Al) is partially formed. On the interlayer insulating film 22 and intermediate wiring layer 24, an interlayer insulating film 26 of silicon oxide (SiO₂) is formed. Further, on the interlayer insulating film 26, an uppermost wiring layer 28 of aluminum (Al) is formed. The lowermost wiring layer 18 and the intermediate wiring layer 24 are connected to each other through a metallic plug 30 which is embedded in the interlayer insulating film 22. The intermediate wiring layer 24 and the uppermost wiring layer 28 are connected to each other through a metallic plug 32 which is embedded in the interlayer insulating film 26. The lowermost wiring layer 18 and the uppermost wiring layer 28 are connected to each other through a metallic plug 34 which is embedded in the interlayer insulating films 22 and 26.

In this way, in the multi-layer wiring layer 10, a current passage connecting the lowermost wiring layer 18 and the uppermost wiring layer 28 is formed by the metallic plugs 30, 32 and 34 and the intermediate wiring layer 24. The metallic plug 34 constituting the current passage is wired over the intermediate wiring layer 24.

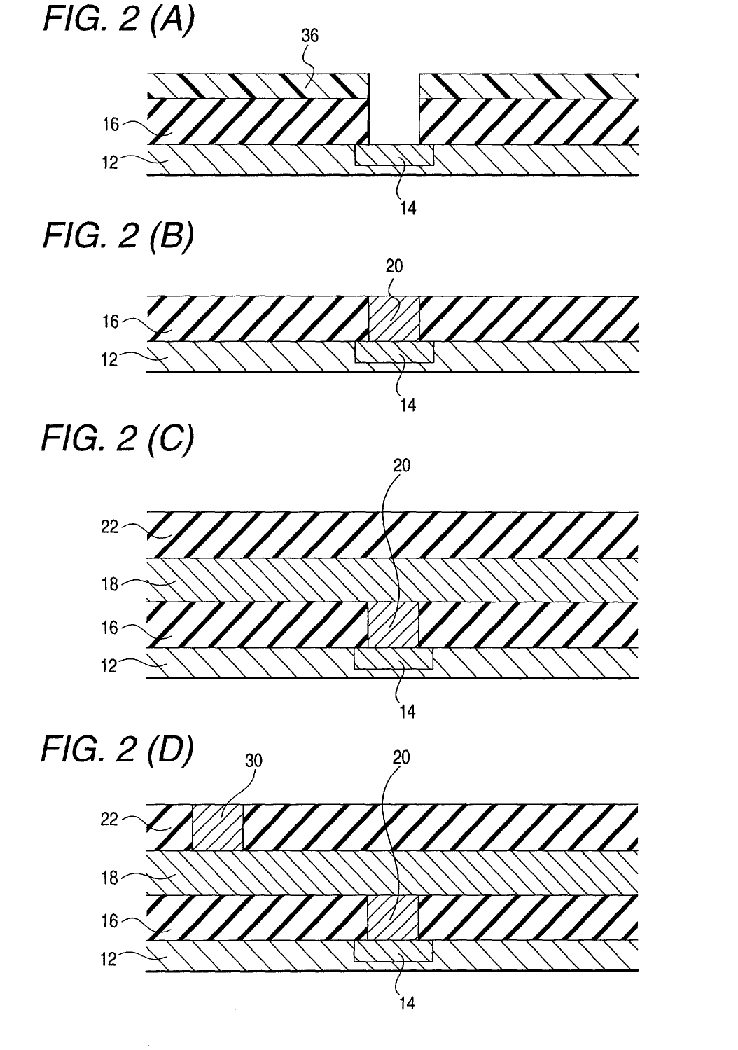

Now referring to FIGS. 2 to 4, an explanation will be given of a concrete method of manufacturing a multi-layer wiring structure 10. First, as seen from FIG. 2A, an interlayer insulating film 16 is stacked on the substrate 2 having the conductive region 14 by the CVD technique. The interlayer insulating film 16 is etched using a resist 36 having a prescribed pattern as a mask to form a connecting hole 38 reaching the conductive region 14. After the resist 36 has been removed, as shown in FIG. 2B, a metallic plug 20 is embedded in the connecting hole 38 by sputtering or CVD technique. Thereafter, the metallic film (not shown) stacked on the interlayer insulating film 16 in the embedding step is etched away. On the metallic plug 20 and interlayer insulating film 16, a lowermost wiring layer 18 is stacked by the sputtering or CVD technique. Further, on the lowermost wiring layer 18, an interlayer insulating film 22 is stacked by the CVD technique. As seen from FIG. 2D, like the metallic plug 20, a metallic plug 30 is embedded in the interlayer insulating film 22.

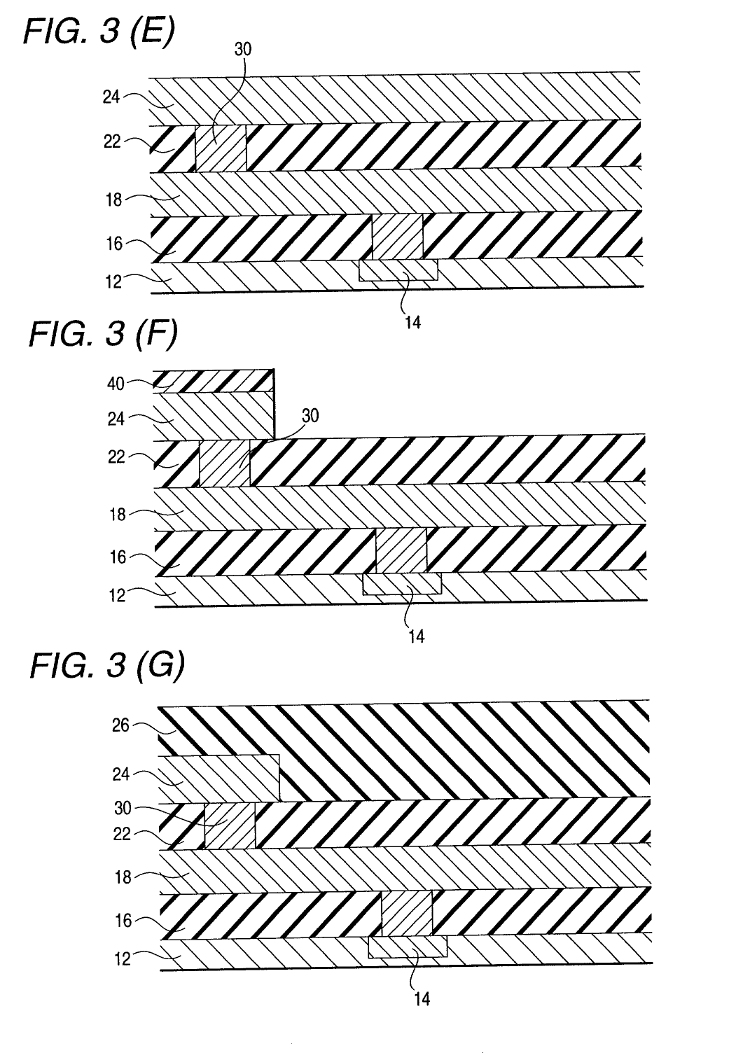

As seen from FIG. 3E, an intermediate wiring layer 24 is stacked on the interlayer insulating layer 22 and metallic plug 30, an intermediate wiring layer 24 is stacked by the sputtering or CVD technique. As seen from FIG. 3F, the intermediate wiring layer 24 is etched using a resist 40 having a prescribed pattern as a mask so that an unnecessary portion of the intermediate wiring layer 24 is removed. After the resist 40 has been removed, as seen from FIG. 3G, on the intermediate wiring layer 24 and interlayer insulating film 22, an interlayer insulating film 26 is stacked by the CVD technique.

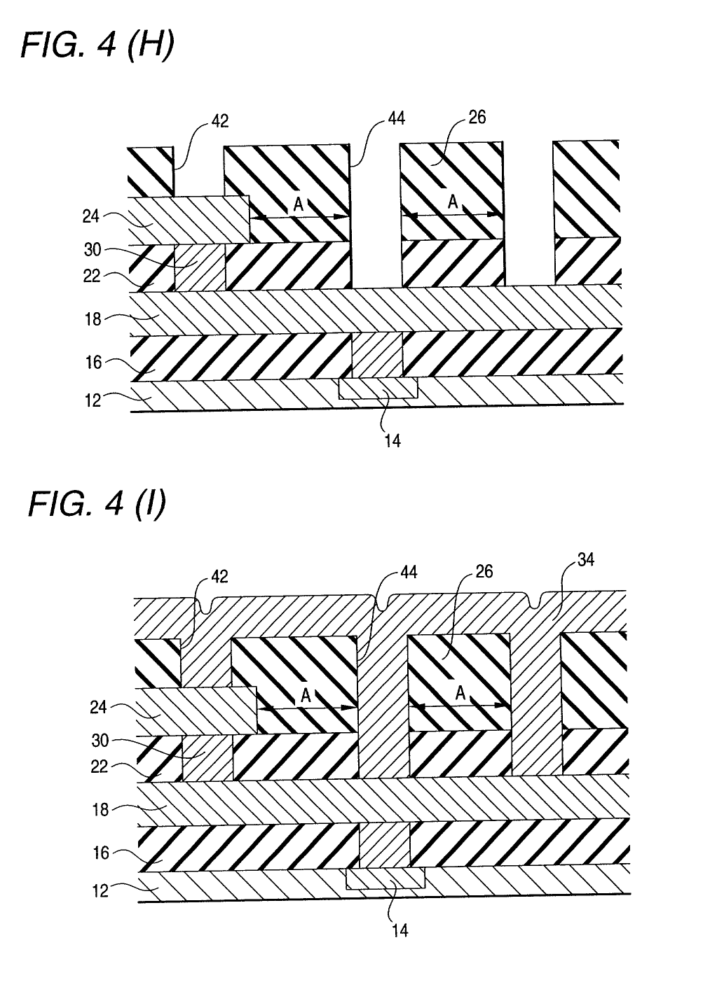

As seen from FIG. 4H, by photolithography and reactive ion etching (RIE), a connecting hole 42 which reaches the intermediate wiring layer 24 is formed in the interlayer insulating film 26. Likewise, another connecting hole 44 which reaches the lowermost wiring layer 18 is also formed in the interlayer insulating film 26 and interlayer insulating film 22. Otherwise, by plotting these holes continuously using FIB (Focused Ion Beam) technique, the connecting holes with a high aspect ratio can be formed. In order to prevent the intermediate wiring layer 24 and metallic plug 34 or the metallic plug 34 and another metallic plug 34 from being brought into contact with each other, the intermediate wiring layer 24 and connecting hole 44, and the connecting hole 44 and another connecting hole 44 must be spaced apart from each other by a prescribed interval A. In this embodiment, the prescribed interval A is set at about 0.4 μm The connecting hole 44 has an aspect ratio of 1.0-5.0 and an opening diameter of 5 μm.

As shown in FIG. 4I, by the high pressure embedding technique, a Cu film W is formed on the substrate on which the connection holes 42 and 44 having a high aspect ratio are formed. The desired Cu film W with no void can be embedded under a high pressure of 700 atoms after sputtering.

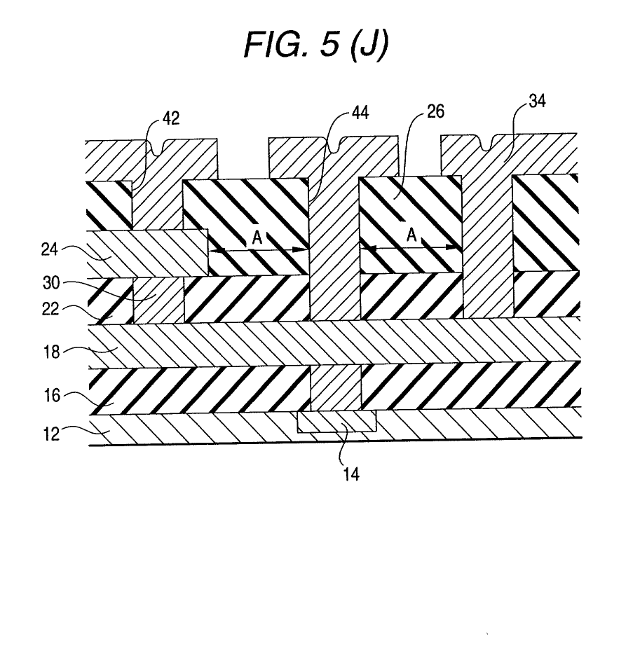

As necessary, as shown in FIG. 5J, the Cu film is patterned by photolithography to complete a multi-layer wiring structure provided with metallic plugs 32 and 34 and wiring pattern 28.

In accordance with the multi-layer wiring structure thus completed, the margins required in the photolithography step to form the intermediate connecting layer and required to form the contact hole over the plural layers are not required. This reduces the wiring area and assures the contact, thereby providing a reliable multi-layer wiring structure.

Additionally, since the connecting hole 44 formed over the interlayer insulating films 26 and 22 have a high aspect ratio, when the metallic plug 34 is embedded in the connecting hole 44, a particular consideration must be taken in order to assure an electric contact with the lowermost wiring layer 18. The metallic plug 34 can be embedded by not only the high pressure embedding technique adopted in the step of FIG. 4I, but also the techniques suited for the connecting hole 44 having a high aspect ratio, such as MOCVD (organic metal-chemical vapor deposition), laser CVD and plating.

In this embodiment, using the high pressure embedding technique, the Cu film was embedded in the connecting hole 44 having a high aspect ratio. As a result, it was found that the high pressure embedding technique provides a very improved embedding property for the connecting hole having a high aspect ratio and a small opening diameter. The inventors of the present invention made embedding with the opening diameter and aspect ratio being varied and measured the yield rate of the multi-layer wiring structure thus manufactured. It was found that the aspect ratio of 1.0-5.0 is desired, and the opening diameter not more than 0.6 μmis desired.

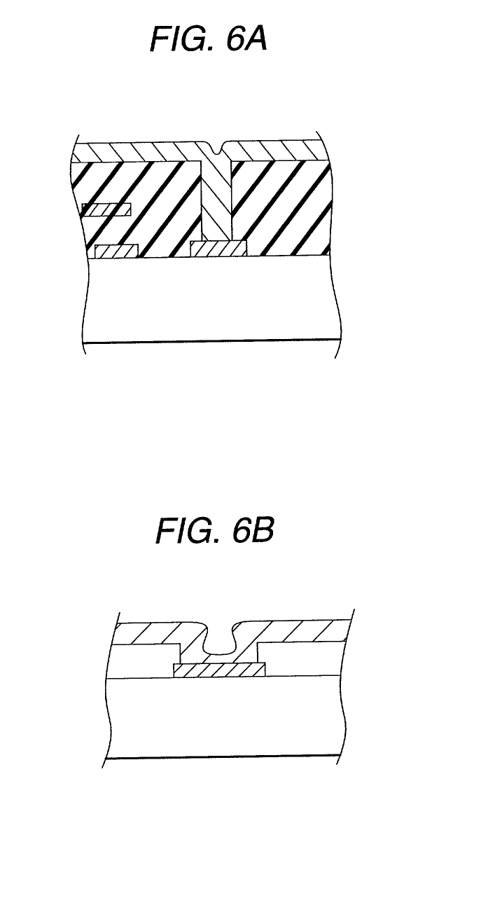

In the case of the connecting hole having a low aspect ratio and a large opening diameter, as shown in FIG. 6B, a void is liable to be formed. However, by selecting the aspect ratio and opening diameter in the above range, when embedding is made for the connecting hole having a high aspect ratio and a small opening diameter as shown in FIG. 6A, it can be carried out with no void and high reliability. This is a very effective means for micromachining. Therefore, using such a technique, a minuscule and reliable multi-layer wiring structure can be obtained.

Incidentally, the high pressure embedding technique can be applied to a method in which a solution containing an organic compound of metal such as copper is applied to a substrate surface and heated under a certain pressure so that a conductive film is embedded in a connecting hole.

Further, in this embodiment, although the metallic plug embedded in the connecting hole and wiring pattern were formed in the same step, after the embedding, the conductive film serving as an uppermost wiring layer may be formed on the surface.

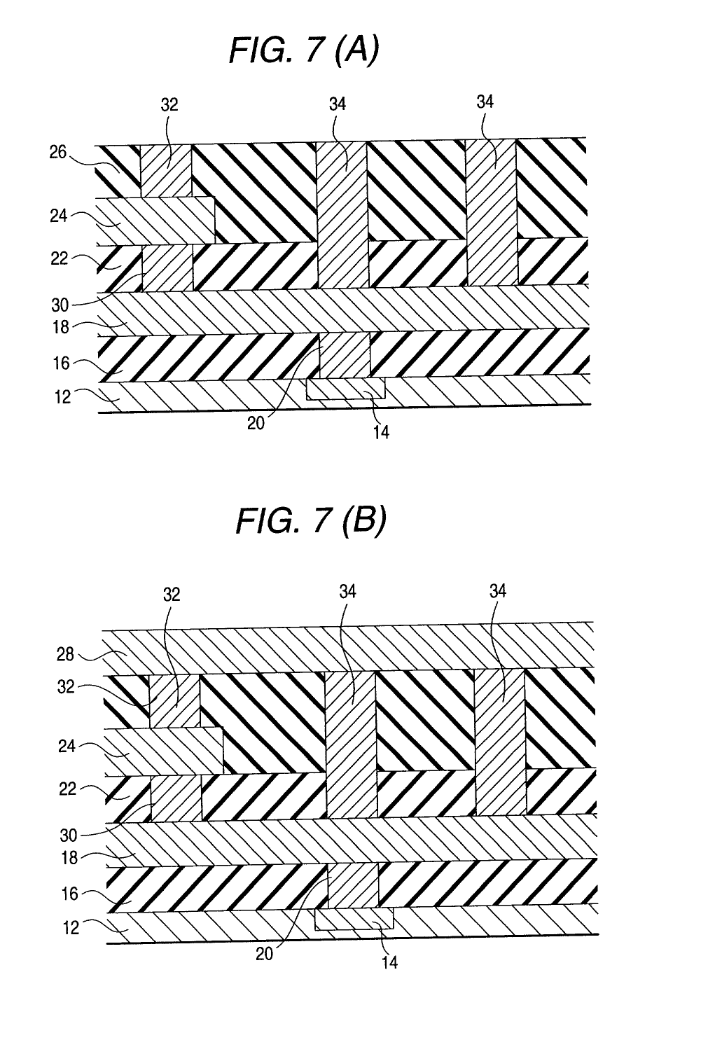

As seen from FIG. 7A, metallic plugs 32 and 34 are embedded in the connecting holes 42 and 44, respectively. Thereafter, as shown in FIG. 7B, on the interlayer insulating film 26 and metallic plugs 32 and 34, an uppermost wiring layer 28 is formed by the sputtering or CVD technique. The unnecessary portion of the uppermost wiring layer 28 is etched away.

The connecting hole 44 formed through both the interlayer insulating film 26 and the interlayer insulating film 22 has a high aspect ratio. Therefore, when the metallic plug 34 is embedded in the connecting hole 44, in order to assure its connection to the lowermost wiring layer 28, particular consideration must be taken. In order to embed the metallic plug 34 in the step shown in FIG. 7A, a technique (e.g. high pressure embedding technique, MOCVD (organic metallic chemical vapor deposition), laser CVD, plating, etc.) suited for making the connecting hole 44 having a high aspect ratio is adopted.

In accordance with this embodiment, the metallic plug 34 is wired over the intermediate wiring layer 24. Therefore, unlike the prior art, it is not necessary to form the connecting layer 7 (FIG. 11) for connecting the upper and lower plugs. Thus, the interval L1 between the intermediate wiring layer 24 and the center of the metallic plug 34 and interval L2 between the respective centers of the metallic plugs 34 are determined depending on the above interval A and the width B of the metallic plug 34. Therefore, as compared with the prior art (FIG. 11), the chip size can be reduced by such a degree that the connecting layer protrudes from the metallic plugs.

In the above embodiment, the present invention was applied to a three-layer wiring structure. However, the present invention can be similarly applied to a four or more layer wiring structure. In this case, a metallic plug 34a may be wired over two or more intermediate wiring layers 24.

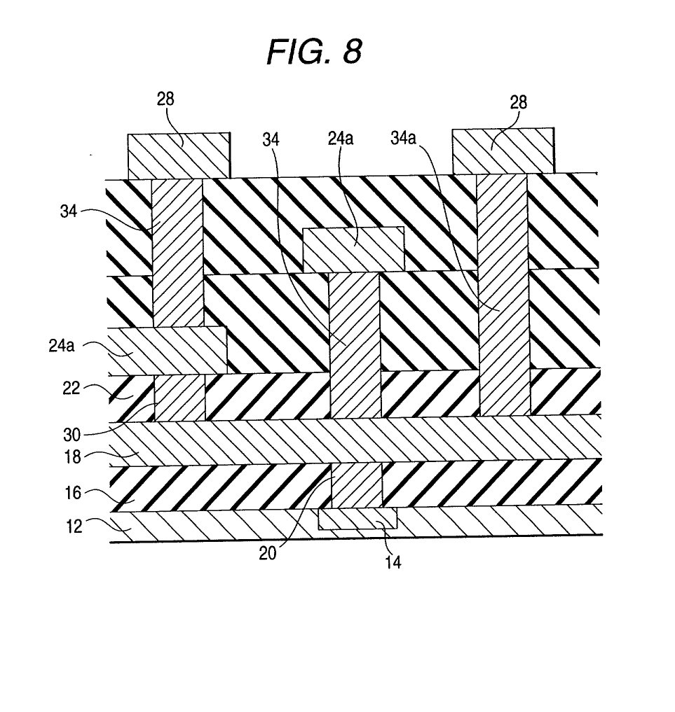

Further, if the wiring layer connected to the lower end of the metallic plug wired over at least one wiring layer is referred to as the first wiring layer, the wiring layer connected to the upper end of the metallic plug is referred to as the third wiring layer, and the wiring layer formed between the first wiring layer and the third wiring layer is referred to as the second wiring layer, for example, as shown in FIG. 8, the first wiring layer may be constructed by not the lowermost wiring layer 18 but the intermediate wiring layer, whereas the third wiring layer may be constructed by not the uppermost wiring layer 28 but the intermediate wiring layer 24b. In this case, it should be noted that the second wiring layer is always constructed by the intermediate wiring layer 24a, 24b, etc

Embodiment 2

An explanation will be given of the second embodiment of the present invention.

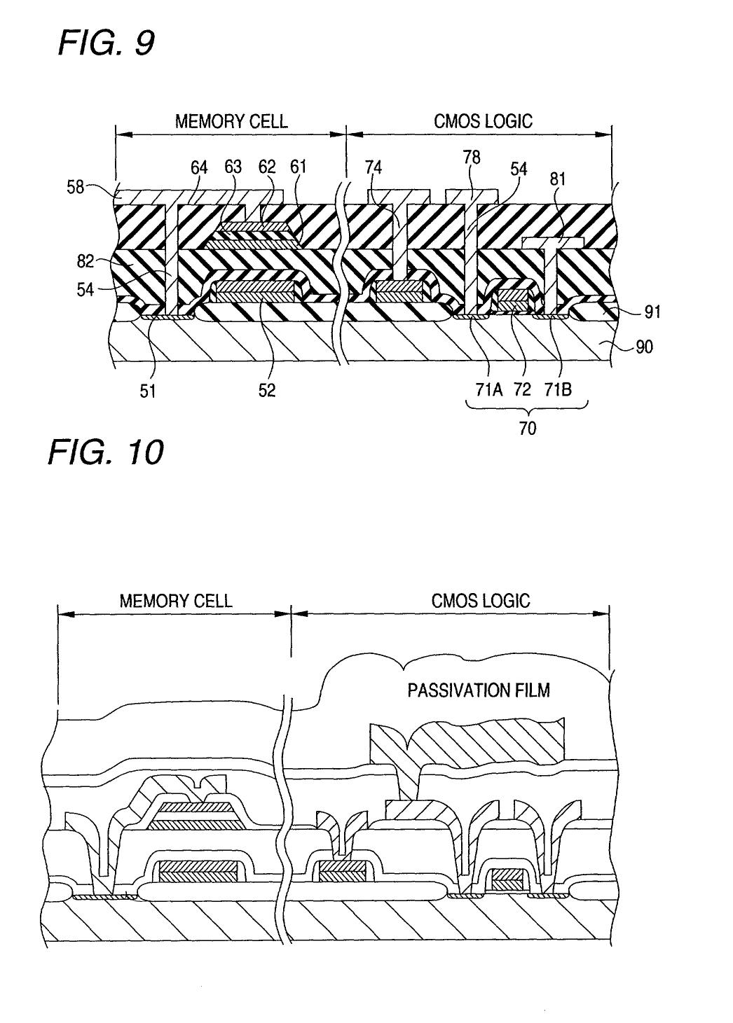

Specifically, as shown in FIG. 9, the explanation will be given of an application of a multi-layer wiring method according to the present invention to a semiconductor memory device using a ferromagnetic memory (FERAM).

The semiconductor memory device includes a memory cell section 100 where FRAMs are arranged in an array and a logic section 200 of CMOS circuits. In such a semiconductor memory device, a memory cell composed of a MOSFET 50 for switching and a ferromagnetic capacitor 60 connected to it and a circuit element 70 such as MOSFET serving as a CMOS circuit are formed as individual circuit elements, and a inter-wiring layer 81 is formed. Further, connecting holes are made from the uppermost layer and its vicinity. By the high pressure embedding technique described above, conductive plugs 54 and 64 are embedded in the connecting holes to make wiring connections.

Specifically, in the memory cell, the MOSFET 50 constituting a switching transistor is composed of source/drain regions 51 (which are impurity diffused regions formed in a silicon substrate 90 by isolated by an element isolation film 91), and the ferromagnetic capacitor 60 has a ferromagnetic film 62 of PZT sandwiched between a lower electrode 61 and an upper electrode 63 on an insulating film 82 covering the substrate surface. One of the source/drain regions 51 of the switching transistor 50 is connected to the upper electrode of the ferromagnetic capacitor in such a manner that the conductive plugs 54, 64 are connected to the uppermost wiring layer 58.

On the other hand, in the CMOS logic section, the MOSFET 70 is composed of source/drain regions 71A, 71B which are impurity diffused region formed in the silicon substrate 90 and a gate electrode 72 formed through a gate insulating film. In this section also, the wiring connection is made on the substrate surface in such a manner that the conductive plugs 54 and 74 formed in the connecting holes are connected to the wiring layer 78.

An explanation will be given of the process for manufacturing the memory device.

First, by the ordinary technique, MOSFETs are formed in the silicon substrate 90 having the isolation insulating films 91 formed by LOCOS.

An insulating film is formed on the resultant surface, a necessary wiring layer 81 and an interlayer insulating film 82 which is made of a silicon oxide film is further formed.

A mask pattern is formed at a time on the entire surface of the silicon oxide film 82 by photolithography. Thereafter, contact holes H are formed by RIE.

By the high pressure embedding technique, metallic conductive films are embedded in the contact holes, and by photolithography, metallic conductive plugs 54, 64 and 74 and metallic wiring layers 58 and 78 are formed.

In accordance with the method described above, almost all the wiring connections between the individual elements can be made in the vicinity of the uppermost layer. Therefore, the number of times of the steps of photolithography can be greatly reduced. Mask alignment is not required so that no margin is required to reduce the cell size. In the CMOS logic section also, the margin for interconnection can be reduced greatly so that the occupied area can be reduced and the thickness can be reduced.

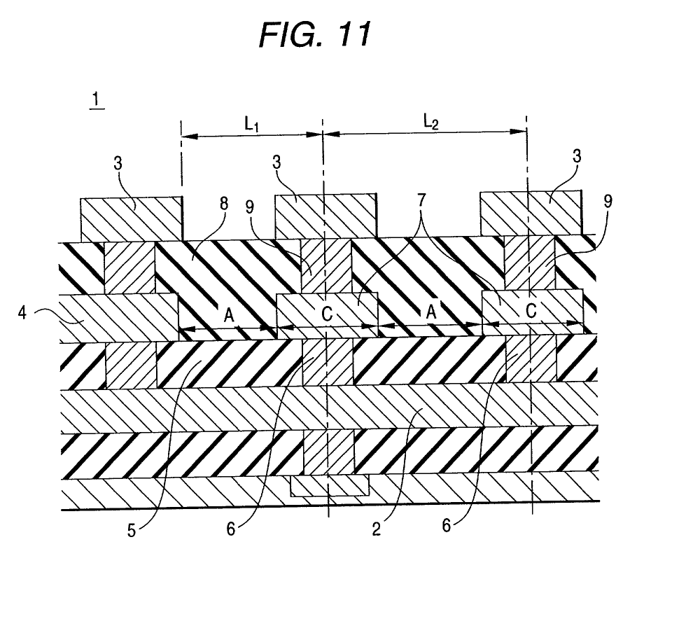

For comparison, a conventional semiconductor memory device using connecting pads is shown in FIG. 10. In FIG. 10, like reference numerals refer to like parts in FIG. 9.

As understood from FIGS. 9 and 10, in accordance with the present invention, the occupied area can be greatly reduced.

What is claimed is:

1. A semiconductor device comprising:
a lowermost wiring layer; an uppermost wiring layer; at least one intermediate wiring layer between the lowermost wiring layer and the uppermost wiring layer; and a current passage which connects the lowermost layer and the uppermost layer, the current passage having a conductive plug which is wired over the at least one intermediate wiring layer.

2. A semiconductor device according to the claim 1, wherein the conductive plug is made of a conductive film which is formed in a connecting hole by a high pressure embedding technique, the connecting hole being formed an insulating film covering the lowermost wiring layer and intermediate wiring layer.

3. A semiconductor device according to the claim 1, wherein the connecting hole has an aspect ratio of 1.0-5.0.

4. A semiconductor device according to the claim 1, wherein the connecting hole has an opening diameter within a range between 0.2-1.0 μm.

5. A method of producing a semiconductor device comprising the steps of:
forming a first wiring layer on a semiconductor substrate;
successively forming, on the first wiring layer, a first interlayer insulating film, a second wiring layer and a second interlayer insulating film;
forming a connecting hole in said first interlayer insulating film and said second interlayer insulating film so as to reach said first wiring layer over said second wiring layer; and
embedding a conductive plug in said connecting hole and forming a third wiring layer thereon.

6. A method of producing a semiconductor device according to the claim 5, wherein the step of embedding a conductive plug is a step of embedding a conductive film by the high pressure embedding technique.

7. A method of producing a semiconductor device according to the claim 5, wherein the connecting hole has an aspect ratio of 1.0-5.0.

8. A method of producing a semiconductor device according to the claim 5, wherein the connecting hole an opening diameter within a range between 0.2-1.0 μm.

9. A method of producing a semiconductor device including a memory cell section composed of a MOSFET for switching and a capacitor connected thereto and a logic section including a CMOS circuit, comprising:
a semiconductor substrate in which MOSFETs for switching and CMOS circuit are formed;
a capacitor formed through a first interlayer insulating formed on a surface of the semiconductor substrate;
a second insulating film covering the capacitor and the entire semiconductor substrate;
conductive plugs formed to pass through the first and the second insulating film, wherein the capacitor and the MOSFETs are connected by connecting the conductive plugs to each other on an uppermost layer on the second insulating layer.

10. A method of producing a semiconductor device according to the claim 9, wherein the capacitor is a ferromagnetic capacitor.
